(19) United States
(12) Patent Application Publication
(10) Pub. No.: US 2026/0365797 A1
(43) Pub. Date: Nov. 19, 2026

(54) PROGRAMMABLE MATERIAL STIFFNESS

(71) Applicant: The University of Chicago, Chicago, IL (US)

(72) Inventors: Aaron Esser-Kahn, Chicago, IL (US); Jun Wang, Chicago, IL (US); Zhao Wang, Chicago, IL (US); Jorge Luis Ayarza-Leon, Chicago, IL (US)

(21) Appl. No.: 19/136,804

(22) PCT Filed: Dec. 8, 2023
(86) PCT No.: PCT/US2023/083228

§ 371 Date: Jun. 6, 2025

Related U.S. Application Data
(60) Provisional application No. 63/386,879, filed on Dec. 9, 2022.

(51) Int. Cl. C08J 3/075; C08K 3/22; C09J 101/02; H10N 30/20; H10N 30/853

(52) U.S. Cl. CPC C08J 3/075; C08K 3/22; C09J 101/02; H10N 30/208; H10N 30/853; C08J 2301/02; C08K 2003/2296; C08K 2201/011

(57) ABSTRACT

Provided are adaptive materials that include a gel that is responsive to electrical input energy. Input electrical energy results in strengthening the gel. In some embodiments, input electrical energy generates chemical promotors for cross-linking reactions and/or linear polymerization via electrochemical transducers and an electrolyte. In some embodiments, the gels include a polymer network and/or polymer network precursors, reactive groups and/or linkers formed by reaction of the reactive groups, an optional electrolyte, and an electrochemical transducer. Also provided are methods of electrically promoted synthesis of polymers and polymer gels.

### INCORPORATION BY REFERENCE

A PCT Request Form is filed concurrently with this specification as part of the present application. Each application that the present application claims benefit of or priority to, as identified in the concurrently filed PCT Request Form, is incorporated by reference herein in their entireties and for all purposes.

### STATEMENT OF GOVERNMENTAL SUPPORT

This invention was made with government support under W911NF-17-1-0598 awarded by the Army Research Laboratory-Army Research Office, and 1710116 awarded by the National Science Foundation. The government has certain rights in the invention.

### FIELD

The present disclosure relates to adaptive materials. In particular, it relates to materials that have mechanical properties that can be varied spatially and temporally with controllable electric input.

### BACKGROUND

Natural materials show fascinating and sophisticated control methods to rapidly sense external stimuli and adapt accordingly. It is highly challenging to mimic such capabilities in synthetic materials such as gels and elastomers.

### SUMMARY

The present disclosure relates to materials having mechanical properties that are responsive to electric fields as programmable input. In some embodiments, the materials include a gel that is responsive to an electric field. In some embodiments, the gels include a polymer network and/or polymer network precursors, reactive groups and/or linkers formed by reaction of the reactive groups, and transducer particles. An electrolyte may be present.

One aspect of the disclosure relates to an organo-gel composition that responds to electrical energy by increasing crosslinking in the composition, wherein the crosslinks remain after the input energy is removed. In some embodiments, the crosslinking is irreversible. In some embodiments, the composition is an adhesive. In some embodiments, the response varies based on frequency of the applied energy. In some embodiments, the response varies based on input time of the electrical energy. In some embodiments, the response varies based on the voltage of the applied energy.

Another aspect of the disclosure relates to a composition including: a polymer network; reactive groups and/or linkers formed by reaction of the reactive groups; and an electrochemical transducer dispersed in the composition. In some embodiments, the composition further includes an electrolyte dispersed in the composition. In some embodiments, the reactive groups include thiol groups and one or both of alkene and alkyne groups. In some embodiments, the reactive groups include thiol groups and acrylate groups.

In some embodiments, the linkers include thioether groups.

In some embodiments, the reactive groups include thiol groups.

In some embodiments, the electrochemical transducer is a piezoelectric material. In some embodiments, the electrochemical transducer includes piezoelectric nanostructures.

In some embodiments, the piezoelectric nanostructures include zinc oxide (ZnO). In some embodiments, the electrochemical transducer is responsive to electrical energy to induce the reaction of reactive groups.

In some embodiments, the polymer network includes crosslinks formed by reaction of the reactive groups.

In some embodiments, the composition further includes a primary polymer network.

In some embodiments, the primary polymer network includes methyl-cellulose.

In some embodiments, the composition is an organo-gel.

In some embodiments, the composition is an adhesive.

Another aspect of the disclosure relates to a system including: a bulk material including an electrochemical transducer; one or more pairs of electrodes configured to apply voltage across the bulk material, each pair configured to apply voltage at a distinct region of the bulk material; and a controller configured to apply voltage at a distinct region according to user input and/or machine-readable instructions stored in memory.

In some embodiments, the bulk material further includes an electrolyte.

Another aspect of the disclosure relates to a method including providing piezoelectric nanoparticles, an electrolyte, and monomers; and subjecting the piezoelectric particles and monomers to electrical energy to thereby form a gel from the monomers.

Yet another aspect of the disclosure relates to a method including providing a first composition including a primary organo-gel, cross-linkable monomers, an electrolyte, and piezoelectric particles; and subjecting the first composition to applied electrical energy to cross-link the cross-linkable nanoparticles and form a double network.

A further aspect of the disclosure relates to a composition including a primary organo-gel, cross-linkable monomers, an electrolyte, and piezoelectric particles.

A further aspect relates to a method of improving conversion efficiency. According to various embodiments, the method involves providing piezoelectric nanoparticles and monomers; and subjecting the piezoelectric particles and monomers to electrical energy to thereby form a polymer from the monomers, wherein the conversion of monomers is at least 0.8. In some embodiments, the conversion is at least about 0.95. In some embodiments, the polymerization proceeds by a thiyl radical mediated polymerization mechanism. In some embodiments, the piezoelectric nanoparticles and monomers are provided with an electrolyte.

These and other aspects of the disclosure are described further below with reference to the drawings.

### BRIEF DESCRIPTION OF DRAWINGS

FIG. 1A schematically illustrates polymerization and cross-linking according to certain embodiments.

FIG. 1B shows a possible reaction mechanism for an electric field-induced thiol-ene reaction.

FIG. 1C shows results of electric-field induced thiol-ene linear polymerization between tri (ethylene glycol) divinyl ether (TEGDE) and 2,2′-(ethylenedioxy) diethanethiol (EDT). The top panel shows the evolution of number-average molecular weight (Mn) over increasing monomer conversion of the polymer via E-thiol-ene polymerization. The bottom panel shows a gel permeation chromatography (GPC) trace depicting the evolution of polymer molecular weight over time.

FIG. 1D shows GPC traces of thiol-ene linear polymerization conducted with different nanoparticles under an AC electric field.

FIG. 1E shows GPC traces of thiol-ene linear polymerization conducted with and without selected nanoparticles under and AC electric field.

FIG. 1F shows high-resolution X-ray photoelectron spectroscopy (XPS) spectra of S 2p, Zn 2p_{3/2}, and Zn 3d regions recorded on pure and EDT treaded nanoparticle samples.

FIG. 1G shows cyclic voltammetry curves for the thiol-ene linear polymerization mixture supernatant before and after undergoing AC electric field. The third curve line represents the CV curve obtained with 0.1 M Zn(BF₄)₂ in dimethylformamide (DMF).

FIG. 1H shows GPC traces of thiol-ene linear polymerization conducted under AC electric field, DC electric field, and stirring conditions for 3 hours.

FIG. 1I shows GPC traces of thiol-ene linear polymerization conducted with platinum (Pt) electrodes inside and outside of reaction vials under AC electric field.

FIG. 1J shows an example of a system to conduct thiol-ene polymerization and crosslinking reactions via electric field control.

FIG. 1K shows examples of linear polymerization and cross-linking reactions.

FIG. 1L shows GPC traces of acrylate-based linear polymerization conducted with Pt electrodes outside of the reaction vials under an AC electric field.

FIG. 1M shows (A) GPC traces and (B) NMR results of disulfide polymerization before and after AC electric field.

FIG. 1N shows GPC traces of E-disulfide polymerization under AC electric field using KI and Et₄NBF₄ as supporting electrolytes.

FIG. 2 is a rendering of a photograph of thiol-ene crosslinking reaction solution. (A) Solution containing ZnO under AC electric field (500 Hz, 8 Vrms, 3 h); (B) Solution without ZnO under AC electric field (500 Hz, 8 Vrms, 3 h) and (C) Solution containing ZnO without electric field. Scale bar: 10 mm.

FIG. 3A shows gelation time as a function of voltage with fixed electrode distance.

FIG. 3B shows storage modulus (G′) response with varied applied voltage.

FIG. 3C shows G′ response with varied frequency of applied voltage.

FIG. 3D shows G′ as a function of reaction time.

FIG. 3E shows time-dependent temperature changed plots for thiol-ene crosslinking gelation conducted (A) under various AC electric fields and (B) with various concentration of 4-methoxyphenol (MEHQ) under AC voltage.

FIG. 4A shows an example setup of electric-field-adaptive properties testing inside a rheometer using oscillatory deformation.

FIG. 4B shows line drawings of images of testing samples on a rheometer. Images of the gelation sample (with ZnO) were captured before (i) and after (ii) applying a 2 Vᵣₘₛ voltage. Images of the control sample (without ZnO) were captured before (iii), during (ii) and after (iv) applying a 2 Vᵣₘₛ voltage.

FIG. 4C shows time sweeps of storage modulus (G′) at 20 °C.

FIG. 4D shows temperature change as a function of time.

FIG. 5A shows a schematic representation of an e-adhesive setup used for electrically induced adhesive testing.

FIG. 5B shows a force vs strain curve for an electrically induced adhesive.

FIG. 5C shows a rendering of a photograph of a multi-stiffness organo-gel obtained after AC voltage application.

FIG. 5D shows the storage modulus of electric field-induced thiol-ene organo-gel as a function of position along the e-adhesive set-up shown in FIG. 5A.

FIG. 6 shows a schematic example of a system for programming a bulk material.

FIG. 7A shows a schematic representation of a device used for adhesion testing including in situ adhesive activation.

FIG. 7B shows a graphical representation of lap shear adhesion test for electro-adhesive (left) and a plot showing force-strain displacement curves for an electro-adhesive after 24 h (right) under 25 °C (left) and 60 °C (right).

FIG. 7C lap shear strength of electro-adhesive, control, and commercial adhesive samples on ITO-coated glass substrates at 25 °C.

### DETAILED DESCRIPTION

The present disclosure relates to materials having mechanical properties that are responsive to electric fields as programmable input. In some embodiments, the materials include a composite gel that is responsive to an electric field. In some embodiments, the composite gels include a polymer network and/or polymer network precursors, reactive groups and/or linkers formed by reaction of the reactive groups, and transducer particles. An electrolyte may be present.

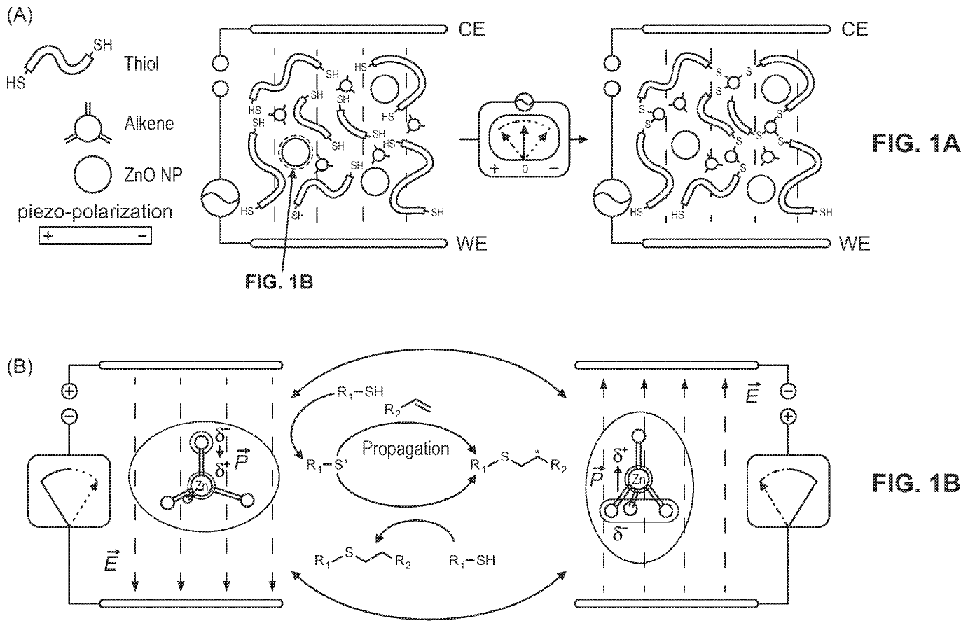

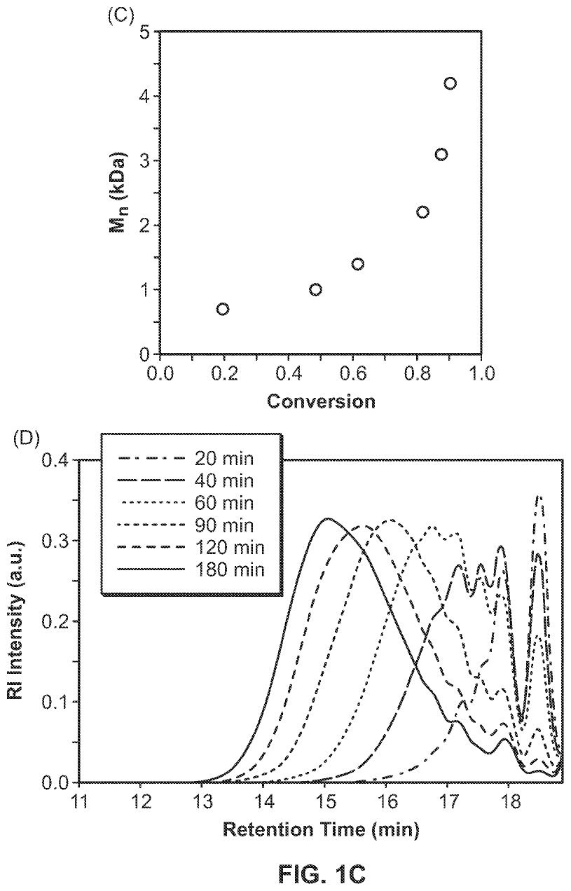

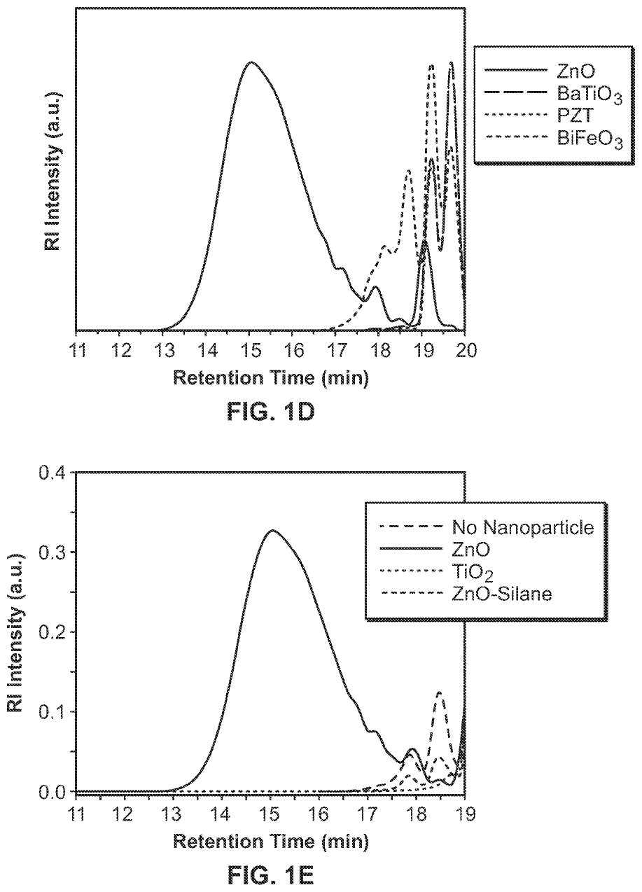

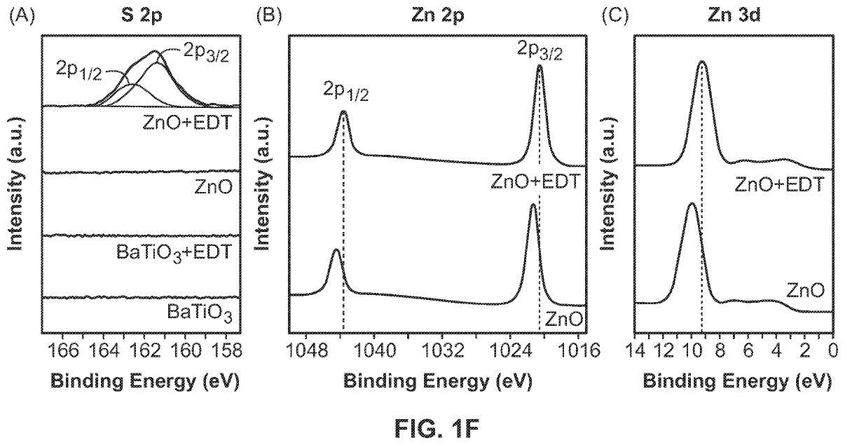

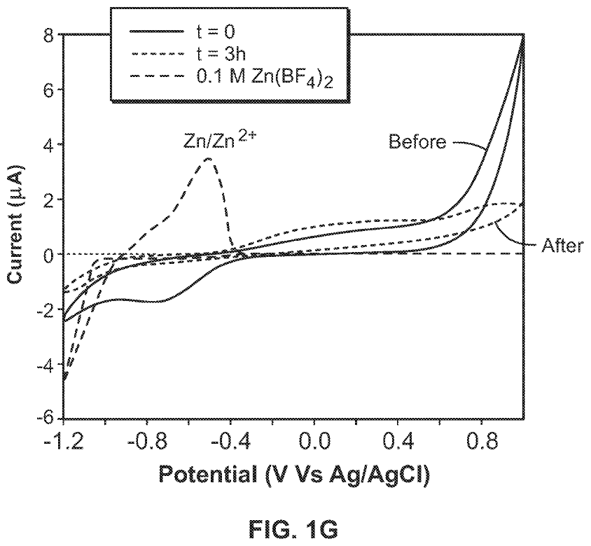

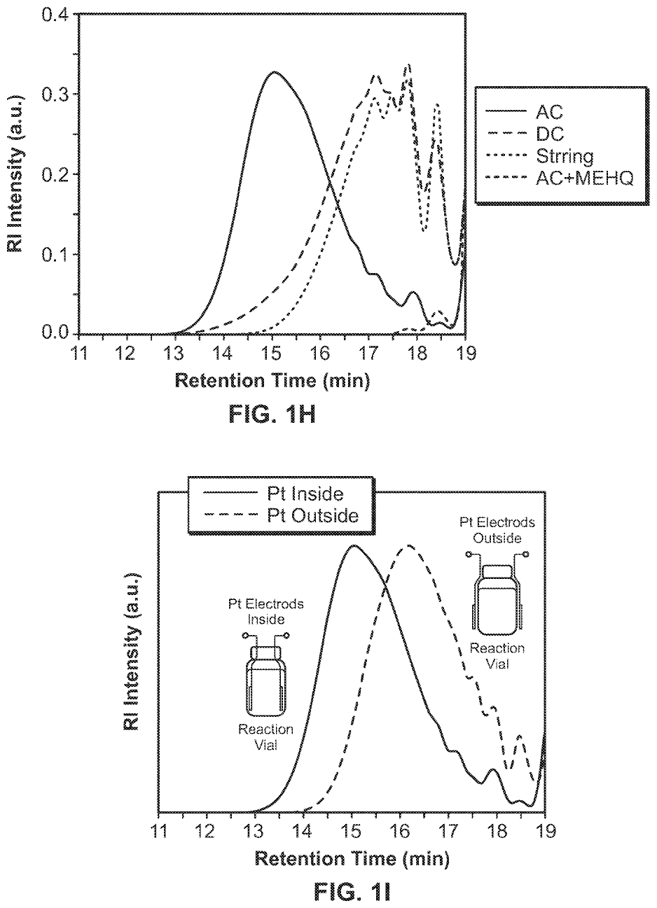

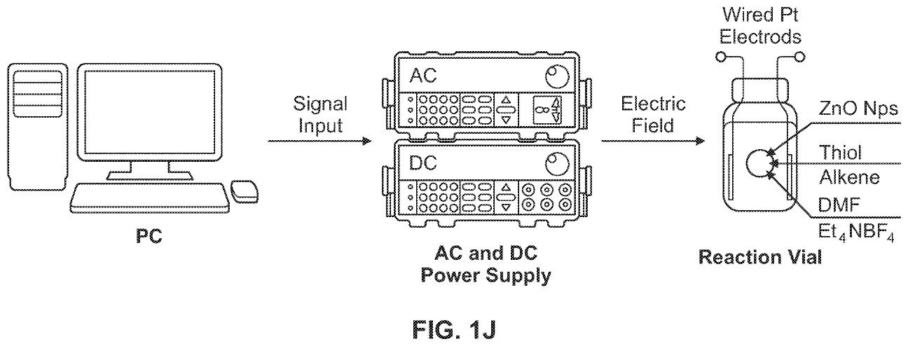

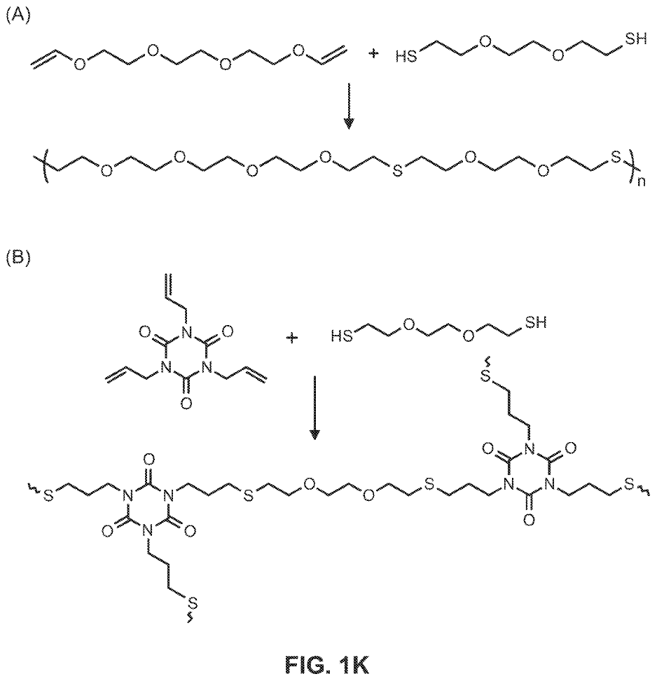

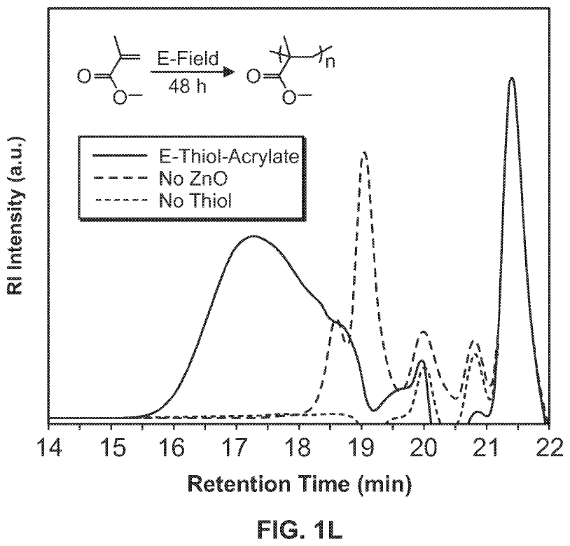

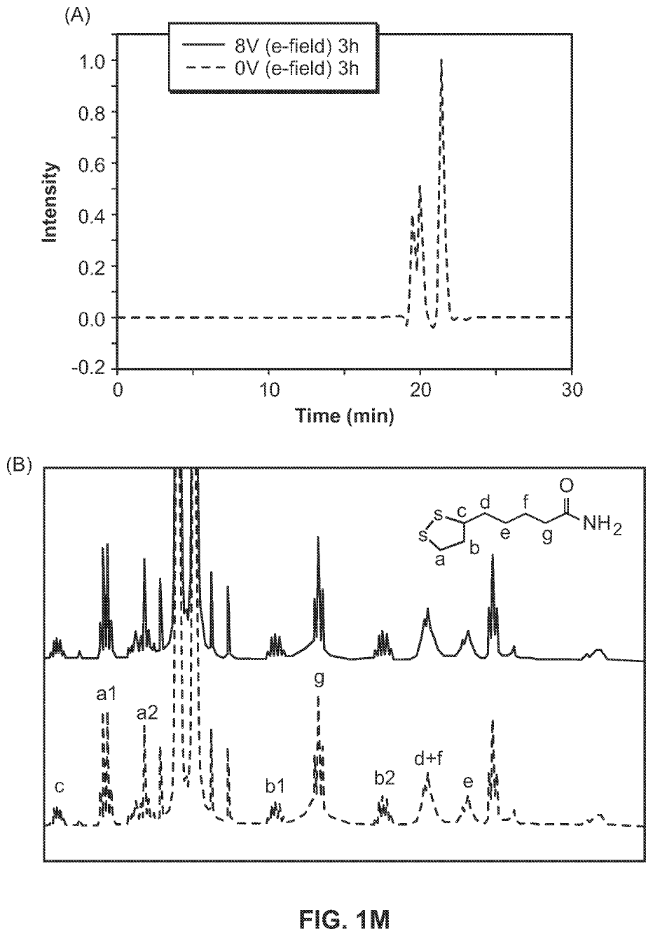

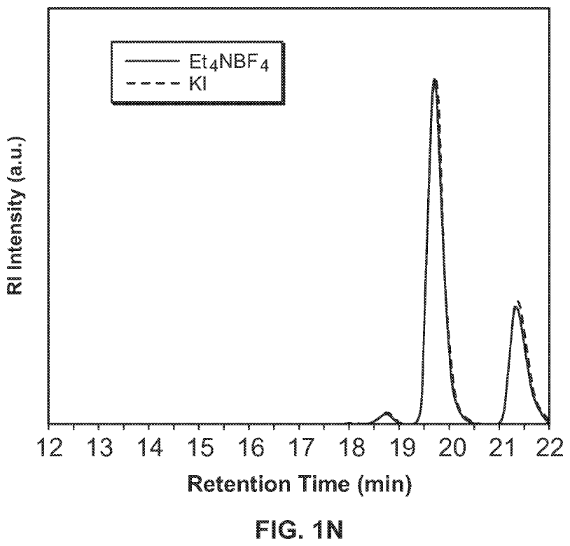

FIG. 1A schematically illustrates polymerization and cross-linking according to certain embodiments. Polymer precursors and electrochemical transducer particles (piezoelectric zinc oxide (ZnO) nanoparticles in the example of FIG. 1A) are subject to an electric field produced by an alternating current. In the example shown, thiol-ene linear polymerization and crosslinking reactions form polymeric networks. This approach enables stiffness manipulation of resulting organo-gels since the electric field can be precisely controlled by adjusting the input signals.

The electrochemical transducer particles may take the form of piezoelectric particles that can transduce electrical energy into chemical energy. Examples include zinc oxide (ZnO) particles. In some embodiments, the particles are nanoparticles, which can be easily dispersed within the polymer to transduce energy at reactive sites throughout the composite. Additional description of appropriate electrochemical transducers is provided below.

According to various embodiments, the composition may include a polymer or linking agent with a thiol group and a polymer or linking agent with a double bond. In some embodiments, the composition includes thioether bonds as products of thiol-ene reactions. According to various embodiments, the composition may include a polymer or linking agent with a thiol group. In some embodiments, the composition includes thioether bonds.

FIG. 1B shows a possible reaction mechanism for an electric field-induced thiol-ene reaction. ZnO nanoparticles serve as a piezo-electrochemical mediator to induce the formation of thiyl radicals, which then promote the chain propagation with an alkene functional group via an anti-Markovnikov addition to form a carbon-centered radical. A chain-transfer step removes the hydrogen radical from the thiol, which can subsequently participate in multiple propagation steps.

According to various embodiments, the composition may include a polymer or linking agent with a thiol group and a polymer or linking agent with a double bond. In some embodiments, the composition includes thioether bonds as products of thiol-ene reactions. According to various embodiments, the composition may include a polymer or linking agent with a thiol group. In some embodiments, the composition includes thioether bonds.

According to various embodiments, gel compositions are provided. The gels may be formed from crosslinked polymers. In some embodiments, a double network gel is provided including a primary matrix (e.g., a methylcellulose (MC) gel) and a network formed from piezo-mediated crosslinked polymers. Other examples of primary gels include polyurethane, siloxanes such polydimethylsiloxane, polyethylene glycol and starch.

### Electrically Controlled Thiol-Ene Polymerization and Gelation

One aspect of the disclosure relates to electrically controlled polymerization and gelation. In some embodiments, a thiol-ene ‘click’ reaction between thiols and alkenes or alkynes may be used with an electrochemical actuator for linear polymerization and/or crosslinking. The following reactive groups (thiol and alkene (A) or alkyne (B)) may be used form thioethers.

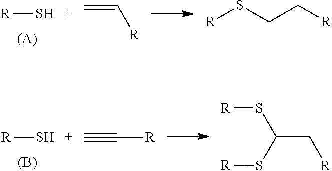

In some embodiments, thiol-ene click components are used with ZnO as a piezo-mediator.

FIG. 1C shows results of electric-field induced thiol-ene linear polymerization between tri (ethylene glycol) divinyl ether (TEGDE) and 2,2′-(ethylenedioxy) diethanethiol (EDT). Tetraethylammonium tetrafluoroborate (Et₄NBF₄) in DMF was used as the supporting electrolyte and piezoelectric ZnO nanoparticles was used as the electrochemical transducer particles. The reaction mixture was subjected to an alternating electric field (8 Vᵣₘₛ, 500 Hz). The experiments were conducted in the dark to eliminate the possibility of light-mediated polymerization. The resulting reaction product was characterized by 1H NMR and gel permeation chromatography (GPC) at 1 h intervals (FIG. 1C).

The top graph of FIG. 1C shows molecular weight (Mn) increase with increasing conversion. The bottom graph of FIG. 1C shows gel permeation chromatography (GPC) traces depicting the evolution of polymer molecular weight over time. Only in the presence of the ZnO nanoparticles, monomers, and electric field, was a polymer (Mn=4200 Da) obtained with very high monomer conversion (90%), showing similar kinetics to a step-growth polymerization. Background polymerization in the presence of ZnO by mechanical stirring (500 rpm) was observed. However, the mechanical activation from stirring is insufficient to achieve the same reactivity as the electric field.

The same process as described above to generate the results in FIG. 1C was performed without ZnO nanoparticles, replacing the ZnO with several piezoelectric nanoparticles (PZT, BaTiO₃, and BiFeO₃). In all cases no reaction was detected indicating that the presence of ZnO nanoparticles is critical for reactivity. FIG. 1D shows GPC traces of thiol-ene linear polymerization conducted with the different nanoparticles under AC electric field (500 Hz, 8 Vrms, 3 h).

The zeta potential under various electric fields under direct current (from 2×103 V/m to 2×104 V/m) was measured. The results shown in Table 1 indicate that the change of electric field led to very little change of surface charges.

TABLE 1
The zeta potential of ZnO nanoparticles
under different DC electric fields.

| DC Voltage (V) | Zeta potential (mV) |
|---|---|
| 5 | −23.0 |
| 10 | −22.3 |
| 20 | −20.9 |
| 50 | −18.1 |

Piezoelectric silane-coated ZnO nanoparticles (1 wt %, about 0.2 nm coating) with a similar zeta potential of −22.6 mV were tested. At the same concentration and electric field, no reactivity was observed, further indicating that ZnO nanoparticles transduce electric fields into reactive electron equivalents on their surface. FIG. 1E shows GPC traces of thiol-ene linear polymerization process conducted with the silane-coated ZnO nanoparticles, uncoated ZnO nanoparticles, photosensitive TiO₂ nanoparticles, and no nanoparticles under AC electric field (500 Hz, 8 Vrms, 3 h). At the same concentration and electric field, no reactivity was observed for the silane-coated nanoparticles, providing further evidence that ZnO nanoparticles transduce electric fields into reactive electron equivalents on their surface.

In some embodiments, the methods involve thiol adsorption onto the nanoparticle surface to obtain piezo-mediated reactivity. To demonstrate this, ZnO and BaTiO₃ nanoparticles were mixed with an EDT solution (2.0 M in DMF). The solution was stirred for 3 hours and then thoroughly rinsed with ethanol. The particles were analyzed by X-ray photoelectron spectroscopy (XPS) to assess the adsorption of thiol.

FIG. 1F shows high-resolution XPS spectra of (A) S 2p, (B) Zn 2p3/2 and (C) Zn 3d regions recorded on the pure and EDT treaded nanoparticle samples. Compared to pure ZnO, in ZnO mixed with EDT both the Zn 2p and Zn 3d peaks exhibited a noticeable shift towards lower binding energy by approximately 0.7 eV. The presence of a strong S 2p peak of thiol treated ZnO in the XPS indicates that the proton was dissociated from the thiol and that EDT bonded to a Zn site at the surface of ZnO. No shifts with the same conditions were observed for BaTiO3. This result provides strong evidence that the binding of EDT directly to the surface of ZnO allows the energy transfer from ZnO to the sulfur atom of the thiol group and provides a piece of the mechanism for electric-field mediated reactivity of ZnO.

To further explore how the electric field affects the ZnO, cyclic voltammetry was conducted to evaluate the possibility of any redox transformation involving Zn. A soluble zinc salt in DMF, Zn(BF₄)₂, was also measured for comparison. No redox peaks were observed within the range from −1.2 to 1.0 V before and after 3 h of applying the electric field (See FIG. 1G). The CV curve of Zn(BF₄)2 showed a redox peak of Zn/Zn2+ reaction at −0.49 V, however, that peak is absent in the CV curves of the thiol-ene mixture, thus indicating there is no soluble Zn2+ present in it, either before or after the application of the electric field.

To investigate whether ZnO generates a free radical equivalent during transduction, 4-methoxyphenol (MEHQ) as a free radical scavenger up to 0.60 mM was added. The inhibition of polythioether formation was observed, indicating that the polymerization was mediated by a radical transfer process.

To investigate the effect of AC or DC electric field on ZnO activation, power was switched from AC to DC voltage (8 V, 500 V/m) for 3 h to explore how the reaction responded when only experiencing a constant electric field. Under DC, less reaction was observed and that after 3 h the reaction ceased coincident with a small amount of reactive material fouling the bulk electrode surface. (See FIG. 1H) This result indicates that DC induction is possible though may result in possible side reactions at these higher electrical potentials.

In certain embodiments, the polymerization process is predominantly mediated by electric field, rather than electric current. Pt electrodes were placed outside a plastic reaction cell to conduct a linear thiol-ene reaction in a black Faraday cage. By using this set-up direct electrical contact between the electrodes and reaction mixture was avoid. FIG. 1I shows GPC traces of thiol-ene linear polymerization conducted with Pt electrodes inside and outside of the reaction cells under AC electric field (8 Vᵣₘₛ, 500 Hz, 3 h). The no-current GPC trace confirms the formation of a polymer with Mn of 3200 Da with no current, providing evidence that neither current nor electron-chemistry is required to mediate a reaction and that the reaction may be predominantly mediated by electric field.

Mechanical activation of ZnO was observed via mechanical stirring (500 rpm). This occurs through a traditional piezochemical reactivity. However, the mechanical activation from stirring is insufficient to achieve the same reactivity as the electric field.

In embodiments described herein, a potential mechanism is the external AC electric field induces the deformation of ZnO nanoparticles following the mechanism of the converse piezoelectric effect wherein the nanoparticles expand and contract. In this way, the quasistatic strains in ZnO nanoparticles may generate internal electrical fields in the opposite direction promoting the generation of thiyl radicals. Orientation of electric field can be fixed by the direct contact of thiols with the ZnO surface and the local piezoelectrically generated electric field at the ZnO surface.

FIG. 1J shows an example of a system to conduct thiol-ene polymerization and crosslinking reactions via electric field control. Electrically-controlled reactions may rely on low strength electric fields (250-1000 V/m) to activate ZnO nanoparticles, which in turn promote the piezochemical generation of radicals and subsequent radical-mediated thiol-ene reaction. This approach enables far-range chemical reactivity within a material, which permanently alters its composition and mechanical properties.

FIG. 1K shows linear polymerization between TEGDE and EDT (A) and crosslinking reaction between 1,3,5-triallyl-1,3,5-triazine-2,4,6 (1H,3H,5H)-trione (TTT) and EDT. As described below, the reaction between EDT and TTT may be used to form crosslinked gels. According to various embodiments, the electrically controlled polymerization may be implemented to form any appropriate polymer or cross-linked gel that can be synthesized using a thiyl radical mediated polymerization mechanism. In one example, thiyl radicals generated by e-field induced chemistry initiate chain polymers of acrylate monomers. FIG. 1L shows GPC traces of acrylate-based polymerization conducted with Pt electrodes outside of reaction vials under AC electric field (50 Vᵣₘₛ, 500 Hz, 48 h). The “no ZnO” and “no thiol” traces represent control reactions that verify that the reaction proceeded according to the mechanism described above.

Notably, little polymerization is observed with disulfide-based monomers, which are not polymerized by a thiyl radical mediated mechanism. FIG. 1M shows GPC traces (panel A) and NMR results (panel B) of disulfide polymerization before and after AC electric field (8 Vᵣₘₛ, 500 Hz, 3 h). In panel (A), the traces are the same indicating no polymerization. The NMR results also demonstrate that no polymer was produced as no monomer peak is reduced and potential new polymer peaks are not observed. (Top NMR plot: before E-field stimulation; bottom NMR plot: 3 h after E-field stimulation). FIG. 1N shows GPC traces of attempted E-disulfide polymerization under AC electric field (8 Vᵣₘₛ, 500 Hz, 3 h) using KI and Et₄NBF₄ as supporting electrolytes. These results also indicate that there is no polymerization even in the presence of supporting electrolytes.

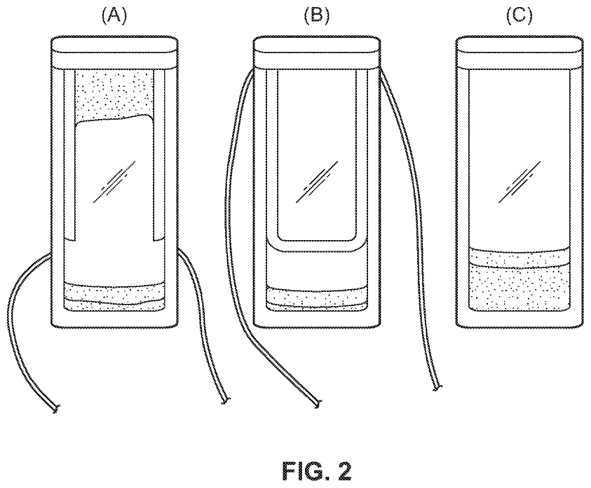

Another aspect of the disclosure relates to electrically controlled crosslinking and gelation. Electrically controlled crosslinking and gelation provides the ability to tune stiffness of the material as desired. EDT and TTT along Et₄NBF₄ with in DMF as the supporting electrolyte and ZnO nanoparticles as electrochemical transducer) were used to create a crosslinked network. Polymerization was carried out leading to a gelation event mediated by electric field. The formed viscoelastic gel sample displayed a storage modulus of 776 kPa at 1 Hz. FIG. 2 is a line drawing of a photograph of (A) a solution containing ZnO under AC electric field (500 Hz, 8 Vrms, 3 h); (B) a solution without ZnO under AC electric field (500 Hz, 8 Vᵣₘₛ, 3 h) and (C) a solution containing ZnO without electric field. The condition for (A) is with all reactants present and under AC electric field (500 Hz, 8 Vrms) for 3 h. ZnO initiated the crosslinking reaction under electric field. After 3 h, a gel formed and can be seen adhered to the top of the reaction vial. The other two vials show the results of the control experiments without ZnO (B) and without electric field (C). There is no reaction with the lack of either the transducer ZnO or the electric field stimulus. No gelation occurs, with the solution remaining as liquid and at the bottom of the vial.

When a DC voltage was applied, a porous gel structure appeared, which was not seen under AC voltage. Space charge accumulation occurs in ZnO dielectric under DC voltage, resulting in cavities and localized breakdown events. These small air voids took effect during the gelation process to form a porous structure. The breakdown failure can be mitigated by AC voltage as it rapidly switches the electrode polarity and constantly drive the space charges out of the dielectric layer.

In some embodiments, a mechanism of thiyl radicals decomposed from thiols is based on the ZnO deformation and relaxation driven by alternating electric field. In such embodiments, regulating electric field such as direction, strength and frequency can control the thiyl radical generation, eventually affecting the gelation process and material stiffness. In some embodiments, electric field strength can be considered a single variable that accounts for all of strength, direction, and frequency.

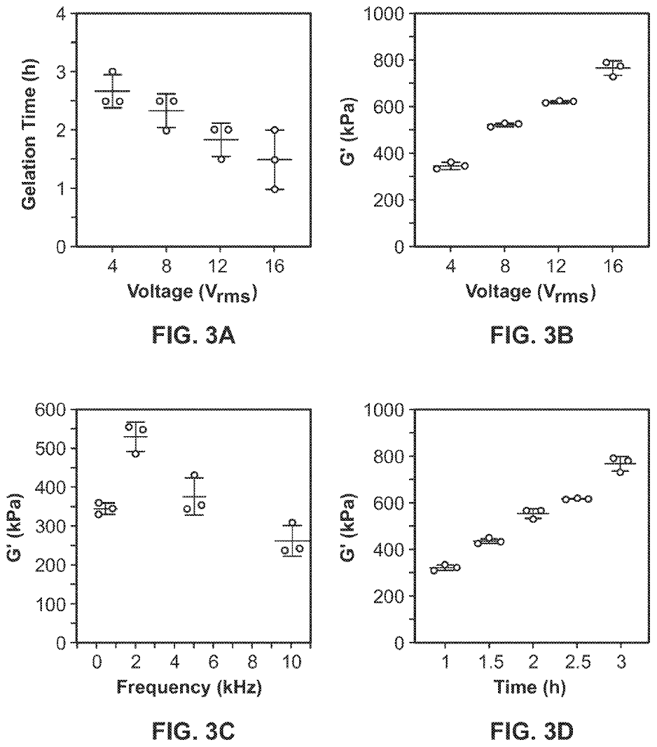

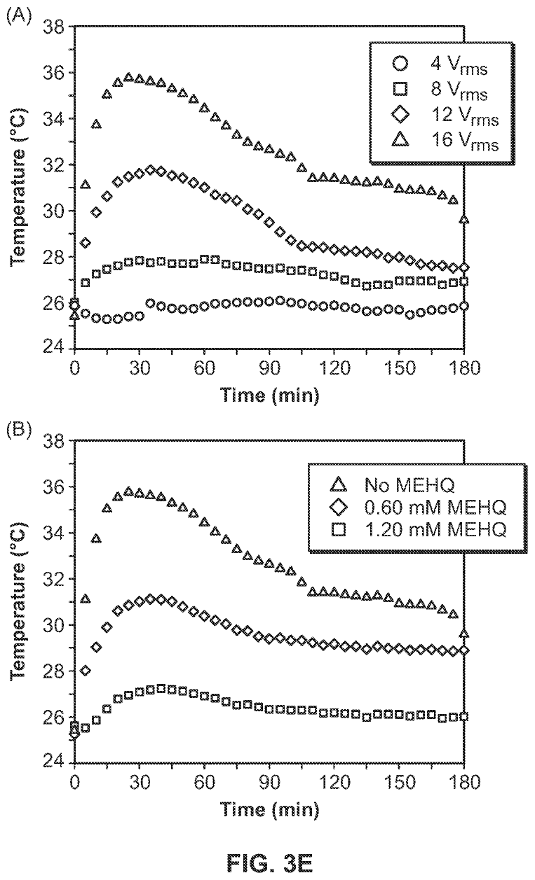

FIG. 3A shows gelation onset time as a function of voltage (Vᵣₘₛ) with fixed electrode distance (16 mm). AC voltage was increased from 4 to 16 Vᵣₘₛ (500 Hz, 250 to 1000 V/m). As shown, higher electric energy resulted in a decreased onset time and higher gelation rate. FIGS. 3B-3D show storage modulus (G′) response to various electrical inputs. FIG. 3B shows G′ of a formed gel increased monotonically from 346 to 776 kPa as a function of increased applied voltage from 4 Vᵣₘₛ to 16 Vᵣₘₛ. This demonstrates that the storage modulus can be controlled by adjusting the input voltage.

Monomer conversion during thiol-ene linear polymerization in the presence of MEHQ (0.30 mM) was measured while varying the applied voltage. As determined by 1H-NMR in and shown below in Table 2, a much higher level of conversion at 16 Vᵣₘₛ (77.9%) was achieved than for the 4 Vᵣₘₛ (7.08%), indicating that increasing the voltage generated more radicals in the same amount of time. Given the exothermic nature of the addition between thiols and terminal alkenes, the time-dependent temperature evolution of thiol-ene gelation at various applied voltage via a temperature sensor was tracked. FIG. 3E shows time-dependent temperature changed plots for thiol-ene crosslinking gelation conducted (A) under various AC electric fields and (B) with various concentration of MEHQ under AC voltage (16 Vᵣₘₛ, 500 Hz). The trend depicted in FIG. 3E reveals that more exothermic energy released with the increasing voltage, which suggests either stronger vibration of the nanoparticles or more addition reactions occur in stronger electric fields.

FIG. 3C shows the response of G′ to the frequency of applied voltage. Voltage amplitude and reaction time were fixed at 4 Vᵣₘₛ and 3 hours, respectively. The storage modulus changed with frequency of electric field, with a peak G′ occurring at 2 kHz. In some embodiments, the response of G′ to frequency may be due to the following mechanism. The crosslinking reaction mediated by ZnO nanoparticles is associated with the dielectric performance and piezoelectric performance of ZnO nanoparticles in bulk solution. The value of the effective dielectric permittivity is inversely proportional to the voltage across the dielectric material present in the system under an applied frequency. While higher dielectric permittivity occurs in the ZnO dielectric at higher frequency, it provides higher voltage across the ZnO-leading to larger ZnO deformation. Once the frequency increases further (above about 2 kHz), the influence of piezoelectric ZnO is dominant and a decrease of piezoelectricity appears as a function of the applied frequency.

FIG. 3D shows the storage modulus as a function of reaction time. The samples were exposed under AC electric field (16 Vᵣₘₛ, 500 Hz, 1000 V/m) with the modulus determined every 30 mins. Longer exposure time leads to more crosslinking and thus higher storage modulus. The gel stiffness progressively rises in the gelation time window, ranging from 330 to 764 kPa in modulus. This trend is consistent with the kinetics of thiol-ene linear polymerization via a step-growth mechanism. It indicates that such a method could be applied to a kinetically controlled crosslinking network formation.

Voltage amplitude, reaction time, and frequency all play critical roles in the modulus-adapting via thiol-ene crosslinking reaction. Each of these parameters alters the modulus of organo-gels, indicating that the material adapts its response to different parameters of electric input parameters. By manipulating an electric field, mechanisms for self-strengthening and/or using a chemo-mechanical feedback loop to create an adaptive modulus response are provided.

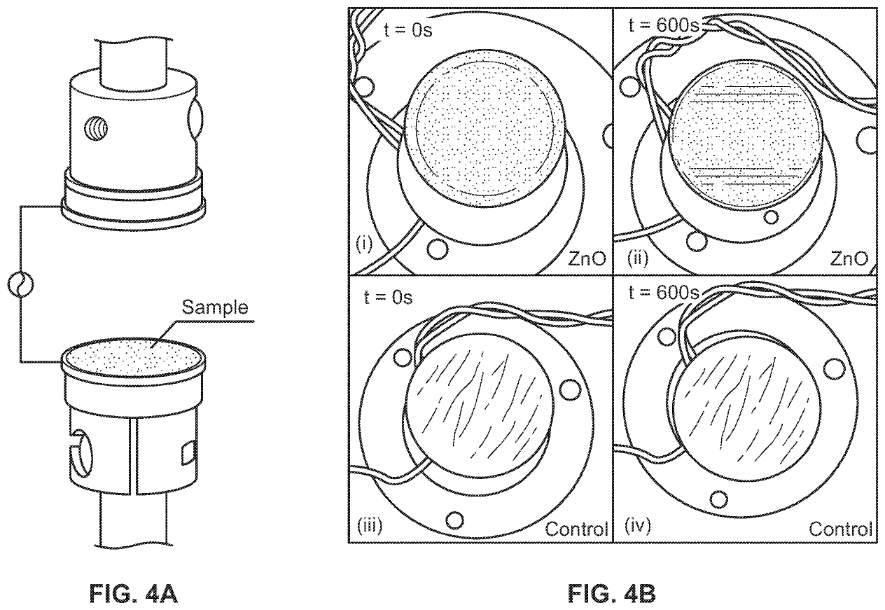

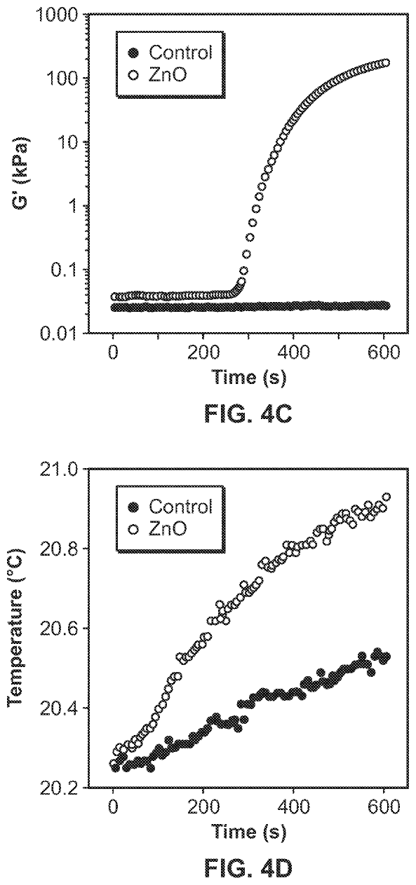

Real-time electrorheology using a discovery hybrid rheometer (DHR) equipped with a dielectric accessory in shear mode at 20 °C (FIG. 4A) was used to determine how quickly gelation occurs. A volume of 0.25 mL of the same formulation of thiol-ene pre-reaction solution was placed on the rheometer plates and the plates placed at 0.5 mm gap distance. With the shortened gap distance, the field strength was calculated to be increased 4 times as an average across the sample at 2 Vᵣₘₛ (4000 V/m) from a 16 Vᵣₘₛ (1000 V/m) bulk experiment. The material had a surprisingly rapid onset time (600 s) at 2 Vᵣₘₛ, 2 kHz while the control group lacking ZnO remained in a liquid state (FIG. 4B).

At very high voltages, there is very modest heating that results from an applied electric field, but it is not enough to greatly alter reaction kinetics. The majority of the temperature increase originates from the exothermic nature of the rapid onset of reaction. Storage modulus and the temperature of the material were measured to determine the influence of the electric field on the rate and/or onset of the reaction. The experimental group showed increased storage modulus from 0.02 kPa to 179 kPa but at an onset time of 270 s (FIG. 4C, ZnO is upper curve, control group lower curve). The mechanical property of e-thiol-ene sample, as determined by strain-stress behavior and frequency-independent moduli, conformed the formation of a robust gel after only 600 s. The control group again did not show the increase of modulus. More notably, coincident with the faster onset time, the ZnO showed an increase in temperature (0.5 degrees Celsius over the control) as the cross-linking reaction released heat (FIG. 4D; ZnO upper curve, control group lower curve). At very high voltages, there is very modest heating that results from an applied electric field, but it is not enough to greatly alter reaction kinetics. The majority of the temperature increase originates from the exothermic nature of the rapid onset of reaction.

In some embodiments, the gels exhibit homogenous controllable adaptation of mechanical behavior induced by an electric field, with all of a bulk material exhibiting the behavior. As described further below, in other embodiments, programmable multiple-modulus gels are provided.

### Programmable Multiple-Modulus Gel

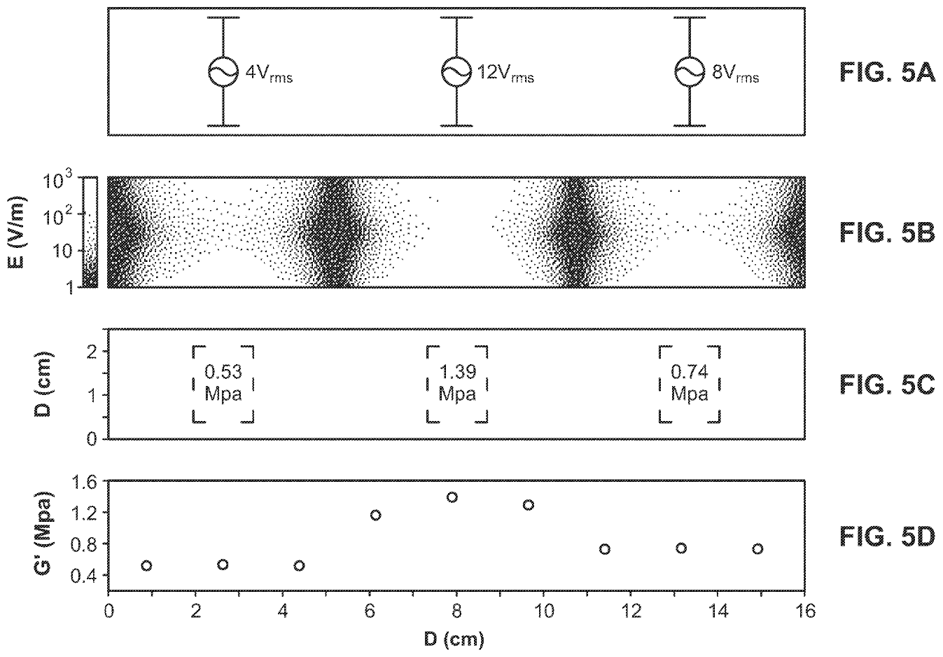

Another aspect of the disclosure is heterogenous stiffness within a bulk material. In some embodiments, systems for programmable spatial control of stiffness are provided. FIG. 5A shows an example of a system including 3 sets of parallel plate electrodes, each configured to deliver AC voltage across a sample. Three pairs of electrodes with configured voltages (4, 12, and 8 Vᵣₘₛ from left to right at 500 Hz) at different position were plugged into an experimental mixture containing ZnO, TTT, EDT and supporting electrolyte in DMF.

FIG. 5B shows results of finite element analysis, demonstrating a linear relationship between the electric field strength and the applied voltage. In the simulation results, neighboring electric fields had little interference. The direction of the electric field was neglected in the simulation because it had no effect on the floating nanoparticles in solution.

FIG. 5C shows a rendering of a photograph of multi-stiffness organo-gel obtained after AC voltage application. The resulting storage modulus at each location is shown on the photograph. FIG. 5D shows the storage modulus as function of location. The obtained modulus in each part that underwent voltage configuration are consistent with the simulated distribution features of electric field. This indicates that stiffness modulation can be localized and controllably dissipated on demand in specific sections, providing flexibility and efficiency to a wide variety of applications. Finite element analysis can be used for the predictive design of tailor-made materials. Patterning a material (either intentionally or as a result of environmental conditions) may be performed by varying the electric field.

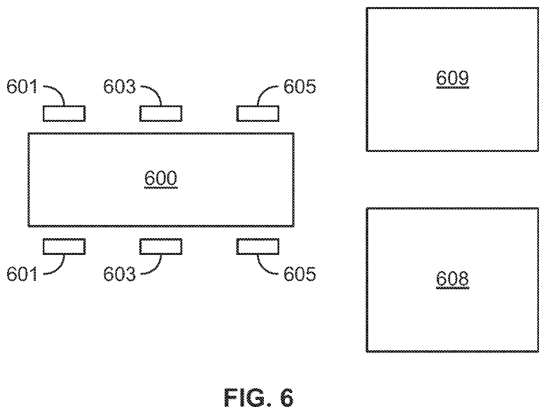

FIG. 6 shows a schematic example of a system for programming a bulk material 600. The bulk material 600 includes a polymer network and/or polymer network precursors, an electrochemical transducer, and an electrolyte. While the bulk material is shown in a rectangle, it may be of any appropriate shape. A mold may be used to appropriately shape or contain the bulk material. For example, a bulk material may be formed to be a medical device, apparel, adaptive damping material, a soft robot material with desirable stiffness in different parts, and a variable rigidity material. In some embodiments, the bulk material may be used in tissue engineering, e.g., for bone or tissue repair.

In the depicted schematic three pairs of electrodes 601, 603, and 605 are shown. A system may have any appropriate number of electrodes arranged as appropriate to change the mechanical properties of a discrete region of the bulk material 600. Each pair of electrodes may be appropriately and individually sized. An electrical power source and controller 609 may be programmed or otherwise configured to control current supplied to and/or to control voltage applied to the electrodes.

A controller may include any number of processors and/or memory devices. The controller may contain control logic such software or firmware and/or may execute instructions provided from another source.

In various embodiments, a controller includes electronics having various integrated circuits, logic, memory, and/or software that receive instructions, issue instructions, control operations described herein. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings or program files, defining operational parameters.

The system may include a user interface 608 that enables entry or programming of parameters and/or settings may then be communicated to the system. In some examples, the controller receives instructions in the form of data, which specify parameters for each of the processing steps to be performed during one or more operations.

### E-Adhesive

Another aspect of the disclosure is an electro-adhesive. The gels described above exhibit adhesive properties. In some embodiments, the gels may be used for adhesion of conductive surfaces by applying a voltage between the surfaces. The adhesion may be enhanced at shorter gap distance, higher voltages, and/or longer time.

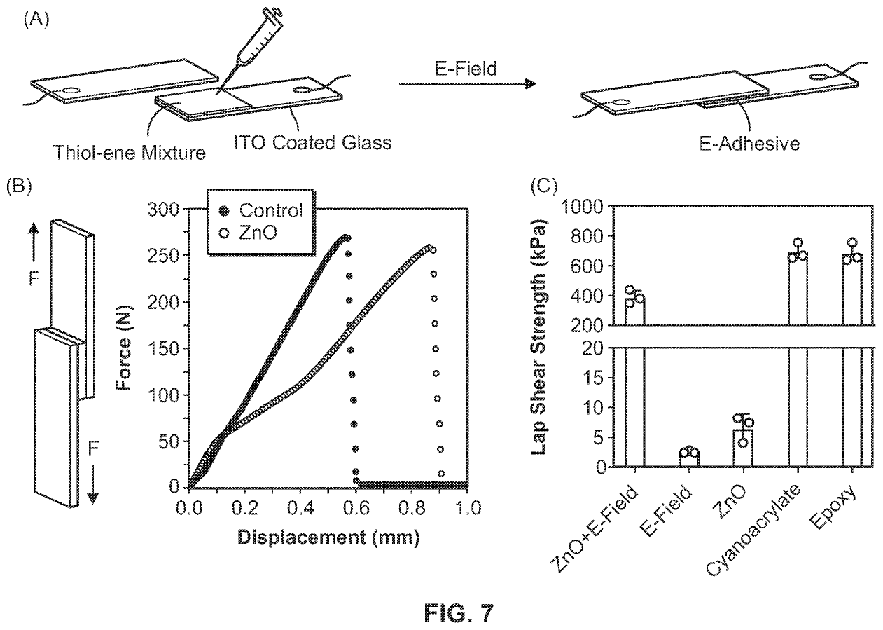

In an example, indium tin oxide (ITO) glass plates were adhered together by deploying a thin layer of the e-thiol-ene reactant solution (0.025 mL) described above. FIG. 7A is a schematic representation of an electro-adhesive setup that can be used for adhesion testing. Adhesion strength under AC voltages at various timescales was measured. After applying the AC (500 Hz, 8 Vᵣₘₛ) for 5 min, lap shear testing to assess shear strength as a measure of the adhesion performance of the electro-adhesive. The dimensions of the adhesive layer were 25 mm×25 mm×0.03 mm. After 24 h, the adhesive sustained 260 N of shear force from 25 °C to 60 °C before loss of integrity. FIG. 7B is a graphical representation of lap shear adhesion test for electro-adhesive (left) and force-displacement curves for electro-adhesive after 24 h under 25 °C and 60 °C (right). The adhesion strength of control samples without electric filed or ZnO nanoparticles was also evaluated. FIG. 7C shows lap shear strength of the electro-adhesive, a control sample, and commercial adhesive samples on ITO-coated glass substrates at 25 °C. As depicted in FIG. 7C, the lap shear strength of electro-adhesive surpasses that of control samples lacking either ZnO or electric field, indicating the strong adhesion occurred by the formation of electric field-triggered thiol-ene crosslinking reaction via ZnO nanoparticles. With the presence of both ZnO and e-field, the strength reaches 389.8±42.0 kPa. This is comparable to commercial cyanoacrylate and epoxy adhesives and higher than previous electro-adhesive (25 to 82 kPa) based on diazrine chemistry. The adhesive strength is consistent with the adhesive strength of these monomers cured via traditional means. Stronger e-adhesives based on the chemistries described herein may be fabricated by tuning the formulations.

When no voltage is applied between the electrodes, the ITO layers can freely slide past one another and the shear strength is dictated by the surface tension. When a voltage is applied, electrostatic forces from aligned dipoles in the dielectric pull the overlapping sections of the electrodes together.

In some embodiments, reconfiguration of the electro-adhesive can be achieved by a direct application of low DC voltages. For example, ITO glass electrodes were connected to an AA battery (3 V, DC) as the electric energy source. After 5 minutes of the 3 V bias, the e-thiol-ene gelation reaction yielded an adhesive that bound the two ITO glass plates together. In contrast, the e-thiol-ene reactant that was not provided with the battery source did not gel, so the ITO glass plates could easily slide off each other.

A peel test for interfacial toughness and lap shear test for shear strength were performed to evaluate the long-term adhesion performance of the electro-adhesive after being adhered for 24 h. See FIG. 5a, which shows a schematic representation of the e-adhesive step used. The dimensions of the adhesive layer were 25 mm×50 mm×0.05 mm. As shown in FIG. 5b, the organo-gel gel can sustain 300 N of shear force. These results confirm that the electric field triggered adhesion has a strong and durable binding.

### Electrochemical Transducers

The electrochemical transducer may take any appropriate form. In some embodiments, they are nanostructures including nanoparticles, nanowires, nanotubes, nanotrees, etc. In some embodiments, the mechano-chemical transducer is dispersed substantially homogenously throughout a material. In some embodiments, the electrochemical transducer may be localized to allow preferential strengthening in one or more regions of a material. In some embodiments, the electrochemical transducer may be attached to a support structure to facilitate localization within a material.

Examples of electrochemical transducers include piezoelectric materials that are responsive to ultrasound and/or lower frequency vibrations and/or electric input. These include ZnO, gallium nitride (GaN), aluminum nitride (AlN), lithium niobate (LiNbO₃), boron nitride (BN), lead zirconate titanate (PZT), barium titanate (BaTiO₃), potassium-sodium niobate (KNN), polyvinylidene fluoride (PVDF), polyvinylidene fluoride-trifluoroethylene (PVDF-TrFE), and polyhydroxybutyrate (PHB). In some embodiments, polymer-modified piezoelectric materials may be used. For example, polymer-modified ZnO can be used to increase contact with the monomers.

### Electric Field

An AC or DC power source may be used to generate the electric field. Power may be continuous, pulsed, or intermittently applied. The electrode placement may vary according to the particular application and desired polymerization. According to various embodiments, the electrodes may or may not be in with the reactive material. Frequency may be varied as described above with example frequencies in the range of 10 Hz to 100 kHz, or 10 Hz to 10 KHz. Voltage may be varied according to the particular application with example potentials in the range of 1 to 20 Vᵣₘₛ.

### Polymer

The gels described herein can include any useful polymer. In some embodiments, the polymers include thiol reactive groups, e.g., to react in thiol-alkene reaction. The polymers may include thioether. In some embodiments, the polymers include alkene or alkyne reactive groups, e.g., to react in a thiol-alkene reaction. In some embodiments, any polymer that can be polymerized by a thiyl-radical mediated reaction mechanism can be used, including polyacrylates.

Non-limiting polymer backbones include poly(ethylene oxide) or poly(ethylene glycol) (PEO or PEG), poly(propylene oxide) (PPO), poly(2-hydroxyethyl methacrylate) (pHEMA), poly(vinyl alcohol) (PVA), poly(acrylamide) (PAAm), poly(acrylic acid) (PAA), polymethylmethacrylate (PMMA), and polystyrene (PS).

In some embodiments, the composition may include one or more prepolymers (e.g., monomers or polymeric precursors including monomers and oligomers). Non-limiting examples include vinyl acetate, ethylene glycol, ethylene oxide, acrylic acid, acrylate, acrylamide, vinyl alcohol, poly(ethylene glycol) divinyl ether, poly(ethylene glycol) diacrylate, and the like. In particular embodiments, the prepolymer includes a vinyl group (e.g., —CH═CH₂), an acrylate group (e.g., —O(CO)—CH═CH₂), a methacrylate group (e.g., —O(CO)—C(CH₃)═CH₂), and ethacrylate group (e.g., —O(CO)—C(CH₂CH₃)═CH₂), and the like.

### Electrolyte

In some embodiments, the composition includes an electrolyte. The electrolyte may be present in solution, as ionic liquid, or as particles dispersed throughout a polymer composition. Examples of electrolytes include quaternary ammonium salts and alkyl ammonium salts. Specific examples include Et₄NBF₄ and triethyl(methyl)tetrafluoroborate Me(Et)₃BF₄. Further examples include tetrabutylammonium perchlorate, tetrabutylammonium hexafluorophosphate, and tetrabutylammonium iodide. Other examples of non-aqueous electrolytes include acetonitrile, propylene carbonate, tetrahydrofuran, diethyl carbonate, and γ-butyrolactone. The electrolyte may dissolve in DMF or other solvent.

An electrolyte may be used to facilitate the ionic transfer and thus increase the reactivity. Thiol-ene gelation may be performed without an electrolyte if the distance between electrodes is sufficiently short and/or the electric field is strong enough.

### Materials and Methods

Tri (ethylene glycol) divinyl ether (TEGDE), 2,2′-(ethylenedioxy) diethanethiol (EDT), 1,3,5-triallyl-1,3,5-triazine-2,4,6 (1H,3H,5H)-trione (TTT), 5-(1,2-dithiolan-3-yl) pentanamide (DPA), methyl methacrylate (MMA), tetraethylammonium tetrafluoroborate (Et₄NBF₄), 4-p-methoxyphenol (MEHQ), zinc tetrafluoroborate hydrate, indium tin oxide (ITO) coated glass slide (70-00 Ω/sq, rectangular) were obtained from Sigma-Aldrich. Chloroform-d (CDCl₃, 99.8%) and 1,3,5-trimethoxybenzene (99.96%) TraceCERT® standards for quantitative NMR were purchased from Sigma-Aldrich. All chemicals were used as received. Dry DMF was obtained after purification using an in-house solvent purification system. ZnO (18 nm, 99.95%), BaTiO₃ (200 nm, 99.9%, tetragonal), ZnO-silane coated (18 nm, 99.95%), and TiO₂ (100 nm, rutile 99.9+%) were purchased from US Research Nanomaterials Inc. Polypropylene cuboid vials (1.70 cm×1.35 cm×3.78 cm) were purchased from United States Plastic Corp. Lead zirconate titanate (PZT, 100-150 nm, 99.9%) and Bismuth Ferrite (BiFeO₃, 80-100 nm, 99.9%) were purchased from Nanoshel LLC. Polypropylene. Platinum foils (0.1 mm thick, 99.99%) were purchased from Thermo Fisher Scientific. Gorilla super glue cyanoacrylate gel was purchased from Amazon.com, Inc. and Hardman double/bubble epoxy glue was obtained from Ellsworth Adhesive.

### Measurements

1H nuclear magnetic resonance (NMR) spectra were recorded on a Bruker AVANCE II+ (500 MHz) spectrometer at 25 °C and processed them in MestReNova 14.2.0.

Gel permeation chromatography (GPC) was conducted in a Shimadzu Prominence LC instrument equipped with Shimadzu Prominence LC-one Agilent PLgel 5 μm MiniMix-D separation column, eluent: stabilized THF (BHT 250 ppm), flow rate: 1 ml min⁻¹, temperature T=25 °C, a Shimadzu UV-VIS detector, a Wyatt DAWN HELEOS II multi-angle light scattering detector (658 nm laser), a Wyatt ViscoStar III detector and a Wyatt OptiLab T-rEX RI detector. The GPC system was calibrated with polystyrene (PS) standards.

Zeta potential measurement was conducted via a Mobius Zeta Potential Analyzer at the sample concentration of 0.2 mg ml⁻¹ in DMF under DC voltage from 5 to 50 V.

X-ray photoelectron spectroscopy (NEXSA G2 Keck-II XPS with monochromatic Al Kα X-ray radiation, emission current of 15 mA and hybrid lens mode, Manchester, UK) was used for the analysis of the surface of nanoparticles. Wide and narrow spectra were measured with pass energy of 80 eV and 20 eV, respectively. XPS spectra were analyzed using Advantage software version 6.6.0 Beta. All spectra were calibrated using C 1s peaks with a fixed value of 284.8 eV.

Mechanical characterization was conducted in a TA Instruments RSA-G2 dynamic mechanical analyzer (DMA) with 25 mm parallel steel plates. The sample was cut and mounted as a cuboid (2.5 mm thick) and compressed up to 0.1 N of force to achieve proper contact between the plates. Preliminary tests were performed to ensure the applied oscillatory strain and the corresponding stress remained in the linear viscoelastic region over the whole temperature range. The frequency sweep experiments were performed at the frequency range from 0.1 Hz to 10 Hz. The compression experiments were conducted at a constant rate of 0.01 mm/s.

Dynamic rheological experiments were performed using a Discovery Hybrid Rheometer (HR-30), TA instruments. The mixture of TTT, EDT and supporting electrolyte in DMF were transferred through pipette to the rheometer. A parallel-plate fixture (25 mm) with a solvent trap was utilized for rheological investigations. The evolution of gel formation as a function of time was captured using small-amplitude oscillatory shear experiments at a strain amplitude of 1% and a frequency of 1 Hz. The gap size was set up to 0.5 mm. The experiments were performed at least three times and representative results were displayed.

Lap shear tests were conducted on the material tester ZwickRoell zwickiLine Z0.5 (500 N loading cell) at 25 °C and 60 °C. The ITO-coated slides with thiol-ene adhesive, control and commercial adhesive samples (25 mm×25 mm×0.03 mm) were prepared and loaded with the tension rate of 10 mm/min.

Cyclic voltammetry (CV) was performed at 25 °C on a Gamry Reference 3000 potentiostat from Gamry Instruments. A platinum disc electrode, platinum wire and Ag/AgCl containing electrode were used as the working, counter and reference electrode, respectively. A typical cycle started from negative potential; the cycle continues by sweeping the potential between +1.2 V to −1.0 V with a scan rate of 0.2 V s⁻¹.

### Electric Field-Induced Thiol-Ene Linear Polymerization

In a typical experiment, ZnO (210 mg, 2.58 mmol) was dispersed in 1.5 mL DMF by ultrasound for 20 seconds and allowed to rest for 30 mins. Two thiol-ene monomers, tri (ethylene glycol) divinyl ether (3 mmol, 606 mg, 0.612 mL) and 2,2′-(ethylenedioxy) diethanethiol (3 mmol, 546 mg, 0.489 mL) and Et₄NBF₄ (0.15 mmol, 32.5 mg) were added to the reaction mixture and took 2 ml mixed solution into a cuboid polypropylene vial. Finally, the plastic vial was directly attached to the power sources (AC or DC power supply) with two wired Pt electrodes. The applied voltages were typically operated at 500 Hz, 8 Vᵣₘₛ for generating alternating electric field unless otherwise noted. Aliquots were collected at intervals and analyzed using 1H-NMR for calculating the conversion.

### Electric Field-Induced Thiol-Ene Crosslinked Gelation

In a typical experiment, 210 mg of ZnO was dispersed in 1.5 mL DMF by ultrasound for 20 seconds and allowed to rest for 30 mins. Two thiol-ene monomers, 1,3,5-triallyl-1,3,5-triazine-2,4,6 (1H,3H,5H)-trione (2 mmol, 499 mg, 0.574 mL) and 2,2′-(ethylenedioxy)diethanethiol (3 mmol, 546 mg, 0.489 mL) and Et₄NBF₄ (0.15 mmol, 32.5 mg) were added to the reaction mixture in a polypropylene vial. Finally, the plastic vial was directly attached to the power sources (AC or DC power supply) with two wired Pt electrodes. A function generator was used to match the efficacy as AC power supply, where the voltage amplitude was configured at the same level (4 Vᵣₘₛ) to allow efficiency comparisons.

### Electric Field-Induced Thiol-Acylate Linear Polymerization

Electric field-induced acrylate-based polymerization was tested with a similar protocol as E-thiol-ene chemistry. Briefly, 200 mg of ZnO were dispersed in 1 mL DMF by ultrasound for 20 seconds and allowed to rest for 30 mins. Then Et₄NBF₄ (0.23 mmol, 65 mg), EDT (0.61 mmol, 112 mg, 0.100 mL), and methyl methacrylate (MMA, 1 mL) were dissolved in the ZnO dispersion consecutively. 2 mL of such mixture was transferred into a plastic vial equipped with two Pt electrode outside. Eventually, the sample was connected to an AC power supply (50 Vᵣₘₛ, 500 Hz) for 48 h.

### Electric Field-Induced Disulfide Polymerization

E-field controlled disulfide polymerization was tested with a modified protocol that is described in a literature (Liu, Y., Jia, Y., Wu, Q. and Moore, J. S., 2019. Architecture-controlled ring-opening polymerization for dynamic covalent poly (disulfide) s. Journal of the American Chemical Society, 141 (43), pp. 17075-17080.). Briefly, 200 mg of ZnO were dispersed in 3 mL DMF first through ultrasonication. Then Et₄NBF₄ (0.3 mmol, 65 mg), 5-(1,2-Dithiolan-3-yl) pentanamide (1 mmol, 205 mg), and EDT (12 μmol, 2.24 mg, 0.002 mL) were dissolved in the ZnO dispersion consecutively. In the end, the mixture was transferred into a plastic vial equipped with two Pt electrode and connected with an AC power supply (8 Vᵣₘₛ, 500 Hz) for 3 h.

### Evaluation of EDT Adsorption on Nanoparticle Surface

In a typical experiment, ZnO (210 mg, 2.58 mmol) or BaTiO₃ (210 mg, 2.58 mmol) was dispersed in 1.5 mL DMF by ultrasound for 20 seconds and allowed to rest for 30 mins. 3 mmol EDT (546 mg, 0.489 mL) was then added into to the suspension in a 50 ml centrifuge tube, and the mixture was vortexed for 3 h under 500 rpm. The resulting suspension was centrifuged at 8,000 rpm for 15 min to drive the nanoparticles to sediment. The supernatant solution was withdrawn using a transfer pipette, enough ethanol was added to bring the total volume of the suspension back to 50 ml, and the mixture was vigorously shaken and centrifuged again. This process was repeated so that a total of three centrifuge steps were performed. Finally, the washed nanoparticles were dried at vacuum oven under 60 °C overnight.

### Evaluation of E-Thiol-Ene Radical Generation

In a typical experiment, ZnO (210 mg, 2.58 mmol) was dispersed in 1.5 mL DMF by ultrasound for 20 seconds and allowed to rest for 30 mins. TEGDE (3 mmol, 606 mg, 0.612 mL), TTT (3 mmol, 546 mg, 0.489 mL), MEHQ (0.15 to 0.60 mmol) and Et₄NBF₄ (0.15 mmol, 32.5 mg) were added to the reaction mixture and underwent three cycles of free-pump-thaw treatment to eliminate dissolved oxygen. Finally, the plastic vial with 2 ml mixed solution was directly attached to the power sources (AC, 4 Vᵣₘₛ, 500 Hz) with two wired Pt electrodes. Aliquots were collected and analyzed using 1H-NMR for calculating the conversion.

### Evaluation of E-Thiol-Ene Linear Polymerization in Glove-Box

In a glove-box equipped with an AC power supply, ZnO (210 mg, 2.58 mmol) was weighed and mixed with 1.5 mL DMF in a sealed tube. The resulting ZnO dispersion was then transferred outside and dispersed by ultrasound (sealed tube with Ar) for 20 seconds and allowed to rest for 30 mins in the glove-box. Subsequently, TEGDE (3 mmol, 606 mg, 0.612 mL), EDT (3 mmol, 546 mg, 0.489 mL) and Et₄NBF₄ (0.15 mmol, 32.5 mg) were added to the reaction mixture and transferred outside the glove-box under Ar protection for three cycles of freeze-pump-thaw treatment to eliminate dissolved oxygen. Finally, the degassed reaction mixture was transferred back to glove-box and 2 ml mixed solution was dispensed into a plastic vial with two wired Pt electrodes inside. Finally, the plastic vial was then directly attached to the AC power sources. The applied voltages were operated at 500 Hz, 8 Vᵣₘₛ for generating alternating electric field at 1-, 5-, 15- and 30-min. Aliquots were collected at intervals and analyzed using 1H-NMR for calculating the conversion.

### Preparation of Programmable Multiple-Modulus Gel

Samples for the experiment were prepared by adding 2100 mg of ZnO to 15 mL DMF by ultrasound for 20 seconds and allowed to rest for 30 mins. Then, TTT (20 mmol, 4990 mg, 5.74 mL), EDT (30 mmol, 5460 mg, 4.89 mL) and Et₄NBF₄ (1.5 mmol, 325 mg) were added to the reaction mixture in a U shape PTFE tunnel sealed with two slides at ends. In this case, multiple electric fields were achieved by fixing the position of parallel electrodes separately while delivering AC voltage in different configuration across the sample. Three pairs of electrodes with configured voltages (4, 12, and 8 Vᵣₘₛ from left to right at 500 Hz) at different position.

### Preparation of Electro-Adhesive

In a typical experiment, 210 mg of ZnO was dispersed in 0.5 mL DMF by ultrasound for 20 seconds and allowed to rest for 30 mins. Two thiol-ene monomers, TTT (2 mmol, 499 mg, 0.574 mL) and EDT (3 mmol, 546 mg, 0.489 mL) and Et₄NBF₄ (0.05 mmol, 10.8 mg) were added to the reaction mixture in a polypropylene vial. Finally, 30 μL of mixture was directly employed to ITO coated glass which wired with the power sources (AC power supply). A series of 2 AA batteries (3 V) were used to supply as DC power source.

### OTHER EMBODIMENTS

All publications, patents, and patent applications mentioned in this specification are incorporated herein by reference to the same extent as if each independent publication or patent application was specifically and individually indicated to be incorporated by reference.

While the invention has been described in connection with specific embodiments thereof, it will be understood that it is capable of further modifications and this application is intended to cover any variations, uses, or adaptations of the invention following, in general, the principles of the invention and including such departures from the present disclosure that come within known or customary practice within the art to which the invention pertains and may be applied to the essential features hereinbefore set forth, and follows in the scope of the claims.

Other embodiments are within the claims.

What is claimed is:

1. A composition comprising:
a polymer network;
reactive groups and/or linkers formed by reaction of the reactive groups;
an electrolyte dispersed in the composition, and
an electrochemical transducer dispersed in the composition.

2. The composition of claim 1, wherein the reactive groups comprise thiol groups and one or both of alkene and alkyne groups.

3. The composition of claim 2, wherein the linkers comprise thioether groups.

4. The composition of claim 1, wherein the reactive groups comprise thiol groups.

5. The composition of claim 1, wherein the reactive groups comprise acrylate groups.

6. The composition of claim 1, wherein the electrochemical transducer is a piezoelectric material.

7. The composition of claim 6, wherein the electrochemical transducer comprises piezoelectric nanostructures.

8. The composition of claim 7, wherein the piezoelectric nanostructures comprise zinc oxide (ZnO).

9. The composition of claim 1, wherein the electrochemical transducer is responsive to electrical energy to induce the reaction of reactive groups.

10. The composition of claim 1, wherein the polymer network comprises crosslinks formed by reaction of the reactive groups.

11. The composition of claim 10, wherein the composition further comprises a primary polymer network.

12. The composition of claim 11, wherein the primary polymer network comprises methyl-cellulose.

13. The composition of claim 1, wherein the composition is an organo-gel.

14. The composition of claim 1, wherein the composition is an adhesive.

15. An organo-gel composition that responds to electrical energy by increasing crosslinking in the composition, wherein the crosslinks remain after the input energy is removed.

16. The organo-gel composition of claim 15, wherein the crosslinking is irreversible.

17. The organo-gel composition of claim 15, wherein composition is an adhesive.

18. The organo-gel composition of claim 15, wherein the response varies based on frequency of the applied energy.

19. The organo-gel composition of claim 15, wherein the response varies based on input time of the electrical energy.

20. The organo-gel composition of claim 15, wherein the response varies based on the voltage of the applied energy.

21. A system comprising:
a bulk material comprising an electrochemical transducer;
one or more pairs of electrodes configured to apply voltage across the bulk material, each pair configured to apply voltage at a distinct region of the bulk material; and a
controller configured to apply voltage at a distinct region according to user input and/or a machine readable instructions stored in memory.

22. The system of claim 21, wherein the bulk material further comprises an electrolyte.

23. A method comprising:
providing piezoelectric nanoparticles, an electrolyte, and monomers; and
subjecting the piezoelectric particles and monomers to electrical energy to thereby form a gel from the monomers.

24. A method comprising:
providing a first composition comprising a primary organo-gel, cross-linkable monomers, an electrolyte, and piezoelectric particles; and
subjecting the first composition to applied electrical energy to cross-link the cross-linkable nanoparticles and form a double network.

25. A composition comprising:
a primary organo-gel, cross-linkable monomers, an electrolyte, and piezoelectric particles.

26. A method comprising:
providing piezoelectric nanoparticles and monomers; and
subjecting the piezoelectric particles and monomers to electrical energy to thereby form a polymer from the monomers, wherein the conversion of monomers is at least 0.8.

27. The method of claim 26, wherein the conversion is at least about 0.95.

28. The method of claim 26, wherein the polymerization proceeds by a thiyl radical mediated polymerization mechanism.

29. The method of claim 26, wherein the piezoelectric nanoparticles and monomers are provided with an electrolyte.
